(19) United States
(12) Patent Application Publication
(10) Pub. No.: US 2008/0052598 A1
(43) Pub. Date: Feb. 28, 2008

(54) MEMORY MULTI-BIT ERROR CORRECTION AND HOT REPLACE WITHOUT MIRRORING

(76) Inventors: Slavek P. Aksamit, Durham, NC (US); Charles Assimos, Cary, NC (US); Cristian Medina, Durham, NC (US)

Correspondence Address: HOFFMAN WARNICK & DALESSANDRO LLC, 75 STATE STREET, 14TH FLOOR, ALBANY, NY, 12207, US

(21) Appl. No.: 11/463,393

(22) Filed: Aug. 9, 2006

(51) Int. Cl. G11C 29/00

(52) U.S. Cl. 714/763

(57) ABSTRACT

The invention is directed to memory multi-bit error correction and hot replace without mirroring. A memory configuration in accordance with an embodiment of the present invention includes: a plurality of memory modules; a memory controller for reading/writing data from/into the memory modules; and an error correcting memory module for storing an error correcting code for each address contained in the plurality of memory modules.

### BACKGROUND OF THE INVENTION

1. Field of the Invention

The present invention generally relates to memory. More specifically, the present invention is directed to memory multi-bit error correction and hot replace without mirroring.

2. Related Art

Current technology and memory configurations allow a system to correct single bit memory errors and detect multi-bit memory errors (e.g., double-bit errors). With the use of memory mirroring, the ability to switch to an exact mirror of the running memory configuration allows for the correction of double bit errors. Although effective, this solution requires a user to half the total available memory in order for it to be mirrored, which can be a very costly solution both monetarily and in system performance. Accordingly, a need exists for a memory configuration that provides multi-bit error correction and hot replace without requiring memory mirroring.

### SUMMARY OF THE INVENTION

The present invention is directed to a memory configuration that provides multi-bit error correction and hot replace without requiring memory mirroring. The memory configuration maintains system availability in the event of a catastrophic DIMM (Dual In-line Memory Module) failure.

A first aspect of the present invention is directed to a memory configuration, comprising: a plurality of memory modules; a memory controller for reading/writing data from/into the memory modules; and an error correcting memory module for storing an error correcting code for each address contained in the plurality of memory modules.

A second aspect of the present invention is directed to a method for error correction, comprising: splitting data into segments; reading/writing each data segment from/into a different one of a plurality of memory modules; storing an error correcting code in an error correcting memory module for each address contained in the plurality of memory modules; and correcting an error caused by a removal or failure of one of the plurality of memory modules using the error correcting code stored in the error correcting memory module, without requiring memory mirroring.

It should be noted that a separate error correcting memory module may not be required. For example, a separate error correcting memory module may not be required if there are enough memory modules available to store the data and the error correcting code for each address in the memory modules containing the data.

The illustrative aspects of the present invention are designed to solve the problems herein described and other problems not discussed.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts an illustrative memory configuration in accordance with an embodiment of the present invention.

The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

As detailed above, the present invention is directed to a memory configuration that provides multi-bit (e.g., double bit) error correction and hot replace without requiring memory mirroring. The memory configuration maintains system availability, for example, in the event of a catastrophic DIMM (Dual In-line Memory Module) failure.

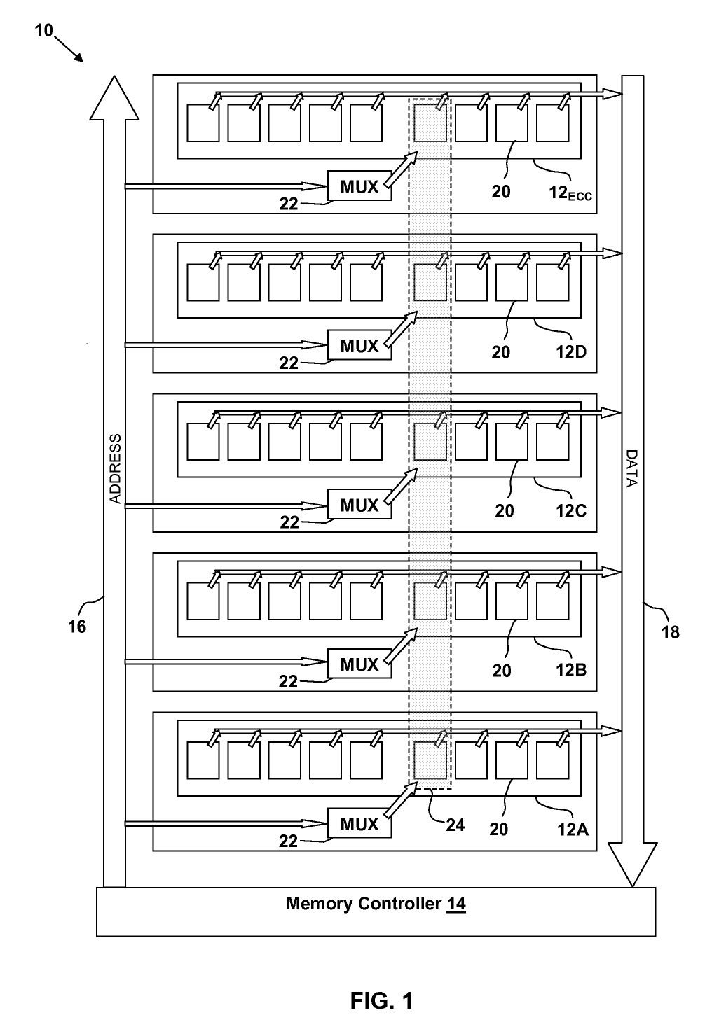

An illustrative memory configuration 10 in accordance with an embodiment of the present invention is depicted in FIG. 1. The memory configuration 10 includes a plurality of DIMMs 12A, 12B, 12C, 12D, and 12_{ECC}, a memory controller 14, an address bus 16, and a data bus 18. Each DIMM 12A, 12B, 12C, 12D, and 12_{ECC} includes a plurality of random access memory (RAM) components 20. One of the DIMMs, namely DIMM 12_{ECC}, is used to provide an Error Checking and Correction (ECC) code for every address contained on the other DIMMs 12A, 12B, 12C, 12D. In this illustrative memory configuration 10, only one of the DIMMs (i.e., DIMM 12_{ECC}) is used for error correction. To this extent, only twenty percent of the total DIMMs are used to support error correction when a DIMM goes bad. This compares favorably to the fifty percent of DIMMs that would be required when using a memory mirroring process of the prior art. Although shown as comprising five total DIMMs 12A, 12B, 12C, 12D, 12_{ECC}, it will be apparent to one skilled in the art that the memory configuration 10 can include any suitable number of DIMMs.

In accordance with the present invention, a data word is read/written on all DIMMs 12A, 12B, 12C, 12D, 12_{ECC} at the same time and in parallel. Specifically, data segments are directed by multiplexer 22 and read/written in parallel on sequential DIMMs. For example, bits 0-3 of a 16-bit data word can be written on DIMM 12A, bits 4-7 written on DIMM 12B, bits 8-11 written on DIMM 12C, and bits 12-15 written on DIMM 12D. An ECC code for every address contained on the DIMMs 12A, 12B, 12C, 12D, provided in any now known or later developed manner, is written to the DIMM 12_{ECC}. The multiplexer 22, positioned before each DIMM 12A, 12B, 12C, 12D, 12_{ECC}, determines which memory component 20 from each DIMM 12A, 12B, 12C, 12D, 12_{ECC} has access to the data bus 18 at any given time, therefore directing different data segments into/from different memory components 20 on the DIMMs. An example of this is represented in FIG. 1 by the shaded box 24.

Using the memory configuration 10, one of the DIMMs 12A, 12B, 12C, 12D can be removed or fail (e.g., due to a multi-bit error), and the system can still correct the error using ECC correction techniques and the ECC code stored on the DIMM 12_{ECC}. Similarly, the failing DIMM 12A, 12B, 12C, 12D can be identified (e.g., using known techniques) and hot-replaced without having to bring the system down. This is done without the use of memory mirroring.

The foregoing description of the embodiments of this invention has been presented for purposes of illustration and description. It is not intended to be exhaustive or to limit the invention to the precise form disclosed, and many modifications and variations are possible.

What is claimed is:

1. A memory configuration, comprising:
a plurality of memory modules;
a memory controller for reading/writing data from/into the memory modules; and
an error correcting memory module for storing an error correcting code for each address contained in the plurality of memory modules.

2. The memory configuration of claim 1, further comprising:
a multiplexer associated with each memory module for determining which of a plurality of memory components on the memory module has access to a data bus.

3. The memory configuration according to claim 1, wherein one of the plurality of memory modules can be hot-replaced using the error correcting code stored on the error correcting memory module, without requiring memory mirroring.

4. The memory configuration according to claim 1, wherein an error caused by a failure or removal of one of the plurality of memory modules can be corrected using the error correcting bits stored on the error correcting memory module, without requiring memory mirroring.

5. A method for error correction, comprising:
splitting data into segments;
reading/writing each data segment from/into a different one of a plurality of memory modules;
storing an error correcting code in an error correcting memory module for each address contained in the plurality of memory modules; and
correcting an error caused by a removal or failure of one of the plurality of memory modules using the error correcting code stored in the error correcting memory module, without requiring memory mirroring.

6. The method of claim 5, further comprising:
hot-replacing one of the plurality of memory modules using the error correcting code stored on the error correcting memory module, without requiring memory mirroring.
